(19) United States
(12) Patent Application Publication
(10) Pub. No.: US 2026/0353835 A1
(43) Pub. Date: Nov. 5, 2026

(54) IMAGE SENSING DEVICE

(71) Applicant: SK hynix Inc., Icheon-si (KR)

(72) Inventor: Sung Wook CHO, Icheon-si (KR)

(21) Appl. No.: 19/343,201

(22) Filed: Sep. 29, 2025

(30) Foreign Application Priority Data
Apr. 16, 2025 (KR) 10-2025-0049663

(51) Int. Cl. H10F 39/00

(52) U.S. Cl. CPC H10F 39/807; H10F 39/8063

(57) ABSTRACT

An image sensing device is provided to include a substrate including a first surface upon which light is incident and a second surface facing or opposite to the first surface; a microlens disposed over the first surface of the substrate; a plurality of photoelectric conversion elements supported by the substrate and arranged adjacent to each other, each photoelectric conversion element configured to receive incident light through the microlens and generate photocharges corresponding to the incident light; and a first pixel isolation structure disposed between the plurality of photoelectric conversion elements within the substrate and configured to isolate the plurality of photoelectric conversion elements from each other. The first pixel isolation structure includes a first portion spaced apart from the first surface and a second portion being in contact with the first surface.

### PRIORITY CLAIM AND CROSS-REFERENCE TO RELATED APPLICATION

This patent document claims the priority and benefits of Korean patent application No. 10-2025-0049663, filed on Apr. 16, 2025, which is incorporated by reference in its entirety as part of the disclosure of this patent document.

### TECHNICAL FIELD

The technology and implementations disclosed in this patent document generally relate to an image sensing device.

### BACKGROUND

An image sensing device is a device for capturing at least one image using semiconductor characteristics that react to light. In recent times, with the increasing development of computer industries and communication industries, demand for high-quality and high-performance image sensors is rapidly increasing in various fields, for example, digital cameras, camcorders, personal communication systems (PCSs), game consoles, surveillance cameras, medical micro-cameras, robots, etc.

Image sensing devices may be broadly classified into charge coupled device (CCD)-based image sensing devices and complementary metal oxide semiconductor (CMOS)-based image sensing devices. Recently, since an analog control circuit and a digital control circuit can be directly implemented as a single integrated circuit (IC), CMOS-based image sensing devices are being widely used.

### SUMMARY

Various embodiments of the disclosed technology relate to an image sensing device capable of alleviating overlay sensitivity by improving a pixel isolation structure configured to isolate photoelectric conversion elements from each other.

In accordance with an embodiment of the disclosed technology, an image sensing device may include: a substrate including a first surface upon which light is incident and a second surface facing or opposite to the first surface; a microlens disposed over the first surface of the substrate; a plurality of photoelectric conversion elements supported by the substrate and arranged adjacent to each other, each photoelectric conversion element configured to receive incident light through the microlens and generate photocharges corresponding to the incident light; and a first pixel isolation structure disposed between the plurality of photoelectric conversion elements within the substrate and configured to isolate the plurality of photoelectric conversion elements from each other. The first pixel isolation structure may include a first portion spaced apart from the first surface and a second portion being in contact with the first surface.

In accordance with another embodiment of the disclosed technology, an image sensing device may include: a substrate including a first surface upon which light is incident and a second surface facing or opposite to the first surface; a plurality of photoelectric conversion elements supported by the substrate and arranged adjacent to each other, each photoelectric conversion element configured to share one microlens and generate photocharges corresponding to the incident light; and a first pixel isolation structure disposed between the plurality of photoelectric conversion elements within the substrate and configured to isolate the plurality of photoelectric conversion elements from each other. The first pixel isolation structure may include a first portion disposed within the substrate and spaced apart from the first surface and the second surface.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

FIG. 1 is a block diagram illustrating an example of an image sensing device according to an embodiment of the disclosed technology.

FIG. 2 is a plan view illustrating an example of a planar structure of some sub-pixel blocks in a pixel region shown in FIG. 1 according to an embodiment of the disclosed technology.

FIG. 3A is a cross-sectional view illustrating an example of the planar structure vertically taken along the line X1-X1′ of FIG. 2 according to an embodiment of the disclosed technology.

FIG. 3B is a cross-sectional view illustrating an example of the planar structure vertically taken along the line X2-X2′ of FIG. 2 according to an embodiment of the disclosed technology.

FIG. 3C is a cross-sectional view illustrating an example of the planar structure vertically taken along the line X3-X3′ of FIG. 2 according to an embodiment of the disclosed technology.

FIG. 4A is a cross-sectional view illustrating an example of a pixel isolation structure horizontally taken along the line XY1-XY1′ of FIG. 3A according to an embodiment of the disclosed technology.

FIG. 4B is a cross-sectional view illustrating an example of a pixel isolation structure horizontally taken along the line XY2-XY2′ of FIG. 3A according to an embodiment of the disclosed technology.

FIG. 5 is a plan view illustrating an example of a planar structure of a unit pixel according to another embodiment of the disclosed technology.

FIG. 6A is a cross-sectional view illustrating an example of the planar structure vertically taken along the line X1-X1′ of FIG. 5 according to another embodiment of the disclosed technology.

FIG. 6B is a cross-sectional view illustrating an example of the planar structure vertically taken along the line X2-X2′ of FIG. 5 according to another embodiment of the disclosed technology.

FIG. 7A is a cross-sectional view illustrating an example of the planar structure horizontally taken along the line XY1-XY1′ of FIG. 6A according to another embodiment of the disclosed technology.

FIG. 7B is a cross-sectional view illustrating an example of the planar structure horizontally taken along the line XY2-XY2′ of FIG. 6B according to another embodiment of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device that can alleviate overlay sensitivity by improving a pixel isolation structure by which photoelectric conversion elements are isolated from each other. In recognition of the issues above, the disclosed technology provides various implementations of the image sensing device that can alleviate overlay sensitivity by improving the pixel isolation structure.

Hereinafter, various embodiments will be described with reference to the accompanying drawings. However, it should be understood that the disclosed technology is not limited to specific embodiments, but may be implemented by various modifications, equivalents and/or alternatives of the embodiments. The embodiments of the disclosed technology may provide a variety of effects capable of being directly or indirectly recognized through the disclosed technology.

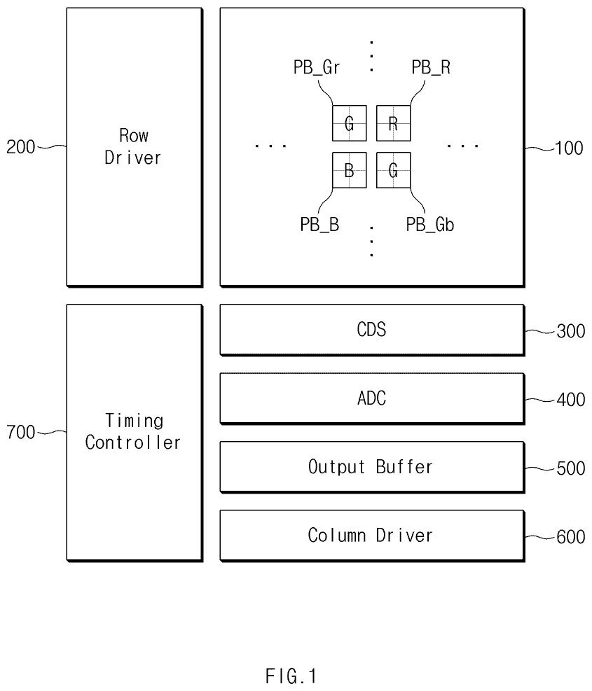

FIG. 1 is a block diagram illustrating an example of an image sensing device according to embodiments of the disclosed technology.

Referring to FIG. 1, the image sensing device may include a pixel region 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel region 100 may include a plurality of sub-pixel blocks (PB_R, PB_Gr, PB_Gb, PB_B) supported by a substrate and consecutively arranged in a two-dimensional (2D) matrix including rows and columns. The sub-pixel blocks (PB_R, PB_Gr, PB_Gb, PB_B) may be arranged in a (2×2) matrix structure with a Bayer pattern. Each of the sub-pixel blocks (PB_R, PB_Gr, PB_Gb, PB_B) may include a structure in which a plurality of unit pixels having the same color is arranged adjacent to each other in an (N×N) matrix structure (where “N” is a natural number greater than or equal to 2). Each unit pixel may include a photoelectric conversion element (e.g., a photodiode PD) that generates photocharges for an electrical signal (e.g., a pixel signal for the unit pixel) through photoelectric conversion of incident light. One microlens may be formed in each sub-pixel block (PB_R, PB_Gr, PB_Gb, PB_B). The structure of the sub-pixel blocks (PB_R, PB_Gr, PB_Gb, PB_B) will be described later in more detail with reference to the attached drawings.

The pixel region 100 may receive driving signals (for example, a row selection signal, a reset signal, a transmission (or transfer) signal, etc.) from the row driver 200. Upon receiving the driving signal, the unit pixels (PXs) may be activated to perform the operations corresponding to the row selection signal, the reset signal, and the transfer signal.

The row driver 200 may activate the pixel region 100 to perform certain operations on the unit pixels in the corresponding row based on control signals provided by controller circuitry such as the timing controller 700. The row driver 200 may generate a row selection signal to select one or more rows from among the plurality of rows. The pixel signals generated by the unit pixels arranged in the selected row may be output to the correlated double sampler (CDS) 300.

The correlated double sampler (CDS) 300 may remove undesired offset values of the unit pixels using correlated double sampling. The CDS 300 may transfer the reference signal and the pixel signal of each of the columns as a correlate double sampling (CDS) signal to the ADC 400 based on control signals from the timing controller 700.

The ADC 400 may convert the CDS signal received from the correlated double sampler (CDS) 300 into a digital signal.

The output buffer 500 may temporarily store column-based data received from the ADC 400 under the control of the timing controller 170.

The column driver 600 may select a column of the output buffer 500 upon receiving a control signal from the timing controller 700, and sequentially output the image data, which are temporarily stored in the selected column of the output buffer 500. Upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

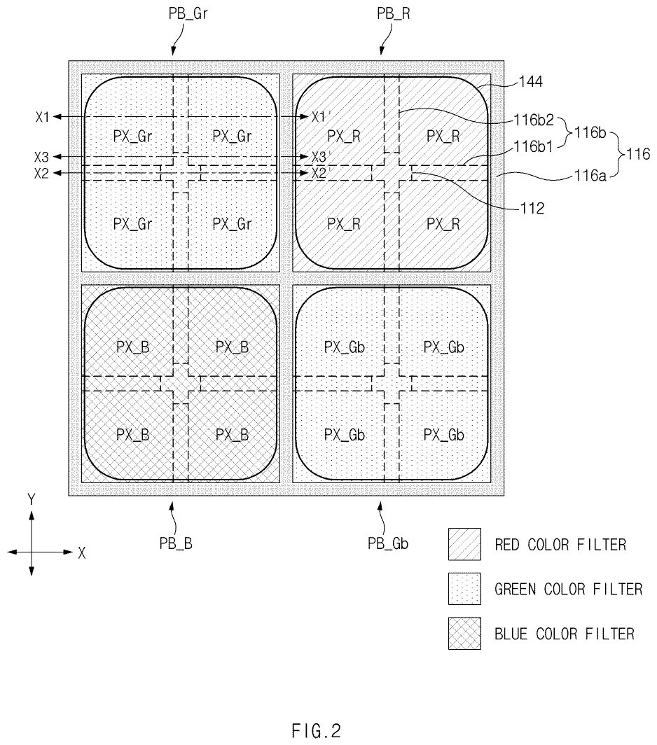

FIG. 2 is a plan view illustrating an example of a planar structure of some sub-pixel blocks in a pixel region shown in FIG. 1 according to an embodiment of the disclosed technology.

Referring to FIG. 2, the pixel region 100 may include a plurality of sub-pixel blocks (PB_R, PB_Gr, PB_Gb, PB_B) consecutively arranged in a first direction (e.g., X-axis direction) and a second direction (e.g., Y-axis direction) intersecting the first direction.

Each sub-pixel block (PB_R, PB_Gr, PB_Gb, PB_B) may include a plurality of unit pixels (PX_R, PX_Gr, PX_Gb, PX_B) arranged adjacent to each other in an (N×N) matrix structure (where “N” is a natural number greater than or equal to 2), and the plurality of unit pixels (PX_R, PX_Gr, PX_Gb, PX_B) of each sub-pixel block (PB_R, PB_Gr, PB_Gb, PB_B) may include a color filter of the same color. One microlens 144 may be formed in each sub-pixel block (PB_R, PB_Gr, PB_Gb, PB_B).

For example, the sub-pixel block (PB_R) may include four unit pixels (PX_R), each of which has a red color filter, arranged adjacent to each other in a (2×2) matrix structure, and the four unit pixels (PX_R) may share one microlens 144. The sub-pixel block (PB_Gr) may include four unit pixels (PX_Gr), each of which has a green color filter, arranged adjacent to each other in a (2×2) matrix structure, and the four unit pixels (PX_Gr) may share one microlens 144. The sub-pixel block (PB_Gb) may include four unit pixels (PX_Gb), each of which has a green color filter arranged adjacent to each other in a (2×2) matrix structure, and the four unit pixels (PX_Gb) may share one microlens 144. The sub-pixel block (PB_B) may include four unit pixels (PX_B), each of which has a blue color filter, arranged adjacent to each other in a (2×2) matrix structure, and the four unit pixels (PX_B) may share one microlens 144. The sub-pixel blocks (PB_R, PB_Gr, PB_Gb, PB_B) may be arranged in a Bayer pattern.

Each unit pixel (PX_R, PX_Gr, PX_Gb, PX_B) may include a photoelectric conversion element disposed within a substrate, and adjacent photoelectric conversion elements may be physically isolated from each other by a pixel isolation structure 116. The pixel isolation structure 116 may include a trench-type isolation structure in which either an insulation material or a combination of an insulation material and a conductive material is buried within a trench formed by etching a semiconductor substrate. The conductive material may include doped polysilicon into which ions are implanted or a metallic material. The insulation material may include a material having a lower light absorption rate than the conductive material. For example, the insulation material may include an oxide.

The pixel isolation structure 116 may include a Back Deep Trench Isolation (BDTI) structure extending from a back surface (e.g., a surface upon which light is incident) of the semiconductor substrate into the substrate.

The pixel isolation structure 116 may include an outer pixel isolation structure (116a) and an inner pixel isolation structure (116b). In the present embodiment, the outer pixel isolation structure (116a) may refer to a pixel isolation structure disposed between adjacent sub-pixel blocks (PB_R, PB_Gr, PB_Gb, PB_B) to surround the photoelectric conversion elements of each sub-pixel block (PB_R, PB_Gr, PB_Gb, PB_B). For example, the outer pixel isolation structure (116a) may be disposed to surround four photoelectric conversion elements that are arranged adjacent to each other in a (2×2) matrix structure for each sub-pixel block (PB_R, PB_Gr, PB_Gb, PB_B), so that the outer pixel isolation structure (116a) may isolate the photoelectric conversion elements from each other in units of sub-pixel blocks (PB_R, PB_Gr, PB_Gb, PB_B). The inner pixel isolation structure (116b) may refer to a pixel isolation structure that is disposed between adjacent unit pixels within each sub-pixel block (PB_R, PB_Gr, PB_Gb, PB_B) and isolates photoelectric conversion elements of adjacent unit pixels from each other. For example, the inner pixel isolation structure (116b) may isolate four photoelectric conversion elements from each other within a region defined by the outer pixel isolation structure (116a).

The inner pixel isolation structure (116b) includes a first isolation portion (116b1) extending in a first direction and a second isolation portion (116b2) extending in a second direction. The inner pixel isolation structure (116b) may be formed in a “+” shape in which the first isolation portion (116b1) extending in the first direction and the second isolation portion (116b2) extending in the second direction intersect at the center of the corresponding sub-pixel block (PB_R, PB_Gr, PB_Gb, PB_B).

In the present embodiment, a central portion of the inner pixel isolation structure (116b) may be defined as a region disposed within a predetermined range from an intersection region where the first isolation portion (116b1) and the second isolation portion (116b2) of the inner pixel isolation structure (116b) cross each other. The remaining region other than the central portion may be defined as a peripheral portion of the inner pixel isolation structure (116b).

In the inner pixel isolation structure (116b), the central portion may be disposed to be spaced apart from the back surface of the substrate by a predetermined distance, and the peripheral portion may be disposed to contact the back surface of the substrate. The same material as the substrate 112 may be disposed in a region between the central portion of the inner pixel isolation structure (116b) and the back surface of the substrate. In addition, the central portion and the peripheral portion of the inner pixel isolation structure (116b) may be spaced apart from the front surface of the substrate. A detailed structure of this inner pixel isolation structure (116b) will be described in detail later with reference to the attached drawings.

The outer pixel isolation structure (116a) and the inner pixel isolation structure (116b) may be connected to each other. For example, both ends of the first isolation portion (116b1) and both ends of the second isolation portion (116b2) of the inner pixel isolation structure (116b) may be connected to the outer pixel isolation structure (116a). The outer pixel isolation structure (116a) and the inner pixel isolation structure (116b) may be formed to have the same width.

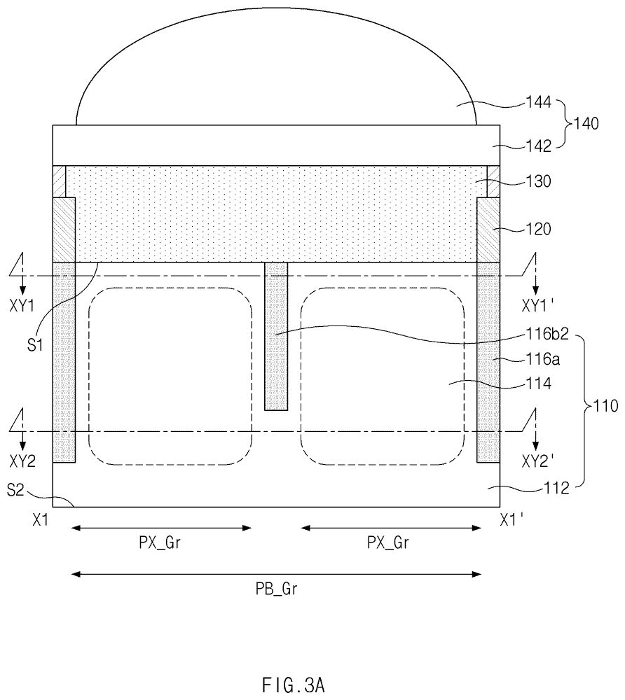

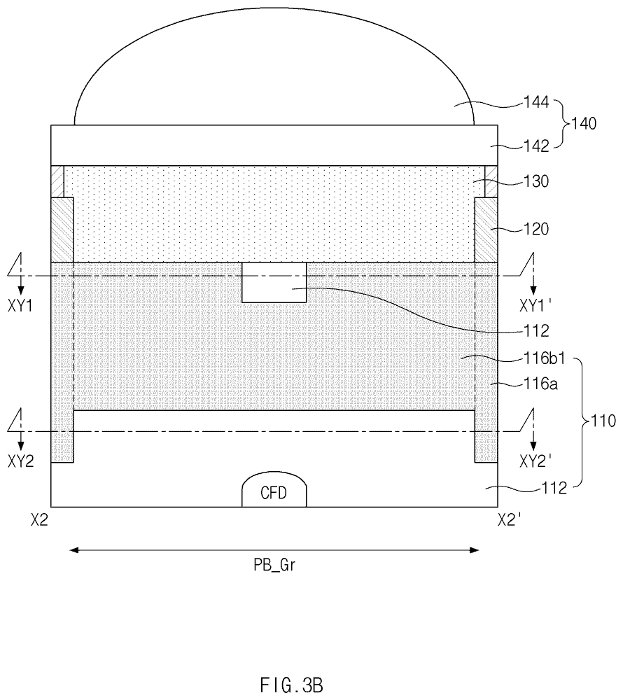

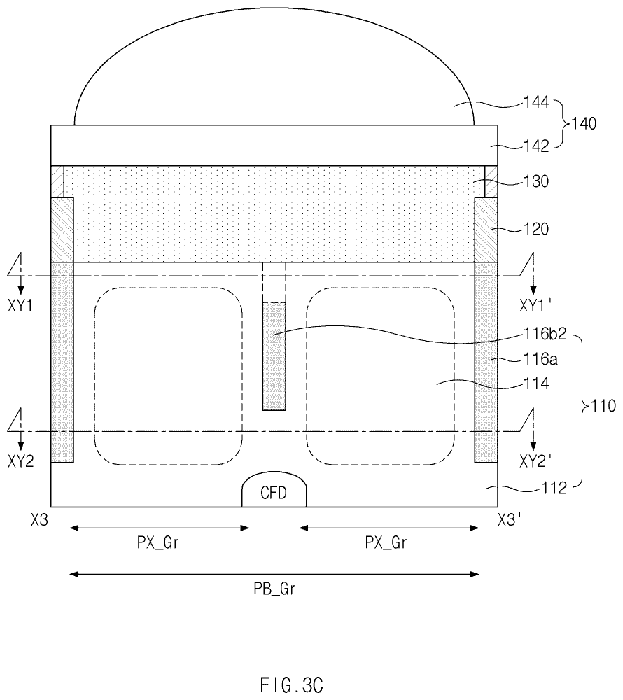

FIG. 3A is a cross-sectional view illustrating an example of the planar structure vertically taken along the line X1-X1′ of FIG. 2. FIG. 3B is a cross-sectional view illustrating an example of the planar structure vertically taken along the line X2-X2′ of FIG. 2. FIG. 3C is a cross-sectional view illustrating an example of the planar structure vertically taken along the line X3-X3′ of FIG. 2.

Since the sub-pixel blocks (PB_R, PB_Gr, PB_Gb, PB_B) may have the same structure except for the color of the color filter, only the structure of the sub-pixel block (PB_Gr) is shown as an example in FIGS. 3A to 3C for convenience of description.

Referring to FIGS. 3A to 3C, the pixel region 100 may include a substrate layer 110, a grid structure 120, a color filter layer 130, and a lens layer 140.

The substrate layer 110 may include a substrate 112; and photoelectric conversion elements 114 and pixel isolation structures (116a, 116b) formed within the substrate 112.

The substrate 112 may include a monocrystalline silicon substrate or an epitaxially grown monocrystalline silicon substrate. The substrate 112 may include a first surface (e.g., a back surface) (S1) and a second surface (e.g., a front surface) (S2) facing or opposite to the first surface (S1). At this time, the first surface (S1) is a surface upon which incident light received from the outside is incident. A grid structure 120, a color filter layer 130, and a lens layer 140 may be formed over the first surface (S1). The second surface (S2) may be a surface on which pixel transistors (not shown) configured to read out an electrical signal caused by photocharges generated by the photoelectric conversion elements 114 are formed. The substrate 112 may include P-type impurities.

The photoelectric conversion elements 114 may be formed to correspond to the unit pixels within the substrate 112. The photoelectric conversion elements 114 may generate photocharges through photoelectric conversion of incident light received through the lens layer 140 and the color filter layer 130. The photoelectric conversion elements 114 of the unit pixels (PX_Gr) belonging to the same sub-pixel block (PB_Gr) may share one microlens 144. Thus, the microlens 144 may be disposed over the photoelectric conversion elements 114 of the unit pixels (PX_Gr) belonging to the same sub-pixel block (PB_Gr). The photoelectric conversion elements 114 of the unit pixels (PX_Gr) belonging to the same sub-pixel block (PB_Gr) are configured to receive light through the microlens 144. In the example, the photoelectric conversion elements 114 may include N-type impurities.

The pixel isolation structures (116a, 116b) may be disposed between adjacent photoelectric conversion elements 114 in the substrate 112 to isolate the photoelectric conversion elements 114 from each other. The pixel isolation structures (116a, 116b) may be classified into the outer pixel isolation structure (116a) and the inner pixel isolation structure (116b). The outer pixel isolation structure (116a) may be disposed between adjacent sub-pixel blocks (PB_R, PB_Gr, PB_Gb, PB_B) to surround each sub-pixel block (PB_R, PB_Gr, PB_Gb, PB_B). The inner pixel isolation structure (116b) may be disposed between adjacent photoelectric conversion elements 114 within a single sub-pixel block. The inner pixel isolation structure (116b) may be disposed in each sub-pixel block (PB_R, PB_Gr, PB_Gb, PB_B).

Each of the pixel isolation structures (116a, 116b) may include a BDTI structure extending from the first surface (S1) of the substrate 112 into the substrate 112. In the implementation, the central portion of the inner pixel isolation structure (116b) may not extend from the first surface (S1) of the substrate 112 but may be spaced apart from the first surface (S1) of the substrate 112 by a predetermined distance. The outer pixel isolation structure (116a) and the inner pixel isolation structure (116b) may extend to have different lengths. The outer pixel isolation structure (116a) may vertically extend in a depth direction from the first surface (S1) of the substrate 112 toward the second surface (S2), but may extend to be spaced apart from the second surface (S2) by a predetermined distance. Alternatively, the outer pixel isolation structure (116a) may extend from the first surface (S1) of the substrate 112 to the second surface (S2) so as to penetrate the substrate 112.

The peripheral portion of the inner pixel isolation structure (116b) may extend vertically in the depth direction from the first surface (S1) of the substrate 112 but may extend to be spaced apart from the second surface (S2) by a predetermined distance. In some implementations, the central portion of the inner pixel isolation structure (116b) may be disposed in the substrate 112 to be spaced apart from both the first surface (S1) and the second surface (S2) of the substrate 112. At this time, the central portion and the peripheral portion of the inner pixel isolation structure (116b) may be spaced apart from the second surface (S2) of the substrate 112 by the same distance. In some implementations, the outer pixel isolation structure (116a) and the inner pixel isolation structure (116b) may be spaced apart from the second surface (S2) of the substrate 112 by different distances. For example, a separation distance between the outer pixel isolation structure (116a) and the second surface (S2) may be shorter than a separation distance between the inner pixel isolation structure (116b) and the second surface (S2). In this case, the separation distance may refer to a distance in the vertical direction.

The central portion of the inner pixel isolation structure (116b) may be formed to extend from the first surface (S1) of the substrate 112 in the same or similar manner as in the peripheral portion, and a region corresponding to a certain depth from the first surface (S1) is etched and removed, so that the central portion of the inner pixel isolation structure (116b) can be formed to be spaced apart from the first surface (S1). At this time, a bottom surface of the region formed when the central portion of the inner pixel isolation structure (116b) is etched may be located below a position at which incident light is focused by the microlens 144.

The substrate region located above the central portion of the inner pixel isolation structure (116b) may be formed through selective epitaxial growth (SEG) after the central portion of the inner pixel isolation structure (116b) is removed.

A floating diffusion region (CFD) shared by the unit pixels of the corresponding sub-pixel blocks (PB_R, PB_Gr, PB_Gb, PB_B) may be formed in a region overlapping the central portion of the inner pixel isolation structure (116b) at the second surface (S2) of the substrate 112. The floating diffusion region (CFD) may include an N-type impurity region extending from the second surface (S2) of the substrate 112 into the substrate 112 by a predetermined depth, and may store photocharges generated by the photoelectric conversion elements 114 and such stored photocharges are used to produce the pixel signal for the unit pixel in each of the sub-pixel block.

The grid structure 120 may be formed between adjacent color filters over the first surface (S1) of the substrate 112 to prevent crosstalk between the adjacent color filters. The grid structure 120 may be disposed to overlap the outer pixel isolation structure (116a) in a vertical direction. In some implementations, the grid structure 120 may not be disposed over the inner pixel isolation structure (116b). For example, the grid structure 120 may not be formed within the sub-pixel blocks (PB_R, PB_Gr, PB_Gb, PB_B) but may be formed between the color filters of adjacent sub-pixel blocks (PB_R, PB_Gr, PB_Gb, PB_B). The grid structure 120 may include a metal (e.g., tungsten).

The color filter layer 130 may include color filters that transmit light of specific wavelengths or colors of visible light from incident light received through the lens layer 140. For example, the color filter layer 130 may include red color filters that are disposed in the sub-pixel blocks (PB_R) and transmit red visible light to the adjacent unit pixels in the sub-pixel blocks (PB_R), green color filters that are disposed in the sub-pixel blocks (PB_Gr, PB_Gb) and transmit green visible light to the adjacent unit pixels in each of the sub-pixel blocks (PB_Gr, PB_Gb), and blue color filters that are disposed in the sub-pixel blocks (PB_B) and transmit blue visible light to the adjacent unit pixels in the sub-pixel blocks (PB_B). The color filters may be disposed in a region defined by the grid structure 120 over the substrate layer 110. For example, a single color filter may be formed in each of the sub-pixel blocks (PB_R, PB_Gr, PB_Gb, PB_B), while the color filter is shared by the four unit pixels.

The lens layer 140 may include an overcoating layer 142 and a plurality of microlenses 144. The overcoating layer 142 may be formed over the color filter layer 130. The overcoating layer 142 may operate as a planarization layer to compensate for (or remove) a step difference caused by the color filter layer 130. The microlenses 144 may be formed over the overcoating layer 142, may converge incident light, and may transmit the converged light to the substrate layer 110. Each of the microlenses 144 may be formed per sub-pixel block (PB_R, PB_Gr, PB_Gb, PB_B). The overcoating layer 142 and the microlenses 144 may be formed of the same materials.

According to the present embodiment, a structure in which four unit pixels of each sub-pixel block (PB_R, PB_Gr, PB_Gb, PB_B) share one microlens 144 is configured such that incident light is accurately focused at an intersection point of the inner pixel isolation structures (116b) by the microlens 144, and the focused incident light is scattered at the intersection point of the inner pixel isolation structures (116b) and evenly distributed to the photoelectric conversion elements 114 of four adjacent unit pixels. However, a manufacturing error can misalign the microlenses 144, causing the incident light to be inaccurately focused at the intersection point. This may prevent the incident light from being evenly distributed to the photoelectric conversion elements 114, instead concentrating it at a specific photoelectric conversion element and causing a severe channel deviation. For example, such misalignment of the microlenses 144 can cause light refraction at the inner pixel isolation structures (116b), leading to channel deviation between pixels. If the inner pixel isolation structures (116b) are not formed, crosstalk may occur between adjacent photoelectric conversion elements 114 within the sub-pixel blocks (PB_R, PB_Gr, PB_Gb, PB_B).

Therefore, the image sensing device according to the present embodiment is configured with the inner pixel isolation structures (116b) formed between the plurality of photoelectric conversion elements 114 that share one microlens 144. The central portion of the inner pixel isolation structures (116b) is removed to a predetermined depth from the first surface (S1) of the substrate 112, upon which light is incident. The removed region may be filled with the same material as the substrate 112. This configuration minimizes channel imbalance between the photoelectric conversion elements 114. This is because even if the microlens 144 is slightly misaligned and the incident light is not focused on the exact center of the sub-pixel blocks (PB_R, PB_Gr, PB_Gb, PB_B), light refraction by the inner pixel isolation structure (116b) does not occur at the central portion of the sub-pixel blocks (PB_R, PB_Gr, PB_Gb, PB_B) where the incident light is focused.

In addition, since the inner pixel isolation structures (116b) are disposed between adjacent photoelectric conversion elements 114 in each of the sub-pixel blocks (PB_R, PB_Gr, PB_Gb, PB_B), occurrence of crosstalk between the photoelectric conversion elements 114 can be prevented.

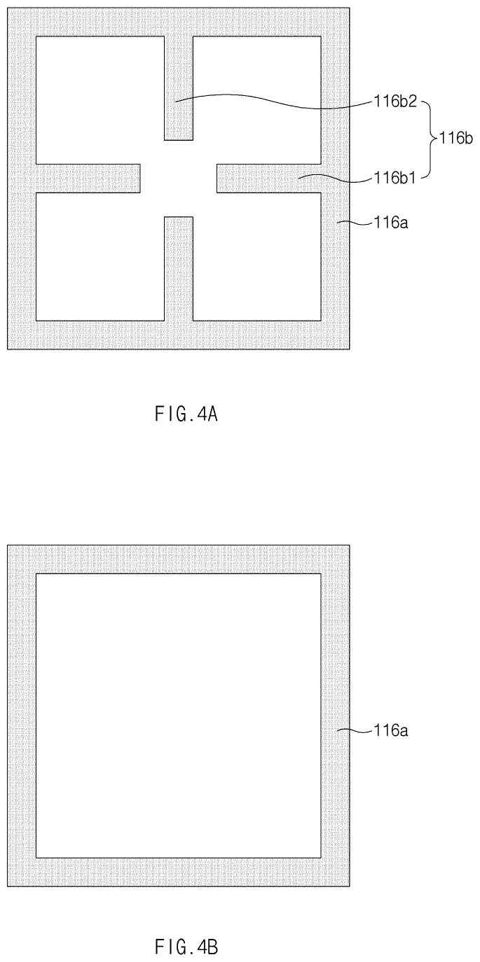

FIG. 4A is a cross-sectional view illustrating an example of a pixel isolation structure horizontally taken along the line XY1-XY1′ of FIG. 3A. FIG. 4B is a cross-sectional view illustrating an example of a pixel isolation structure horizontally taken along the line XY2-XY2′ of FIG. 3A.

Referring to FIG. 4A, the outer pixel isolation structure (116a) and the peripheral portions of the inner pixel isolation structure (116b) may be formed in a region adjacent to the first surface (S1) within the substrate 112. In the implementations, the central portion of the inner pixel isolation structures (116b) may not be formed in the region adjacent to the first surface (S1) within the substrate 112. For example, while the outer pixel isolation structure (116a) and the inner pixel isolation structure (116b) may be formed as a BDTI structure extending from the first surface (S1) of the substrate 112 into the substrate 112, the central portion of the inner pixel isolation structure (116b) may be removed from the first surface (S1) to a predetermined depth, so that the resultant central portion can be spaced apart from the first surface (S1) by the predetermined depth.

Referring to FIG. 4B, the outer pixel isolation structure (116a) may be formed in a region adjacent to the second surface (S2) within the substrate 112, whereas the inner pixel isolation structure (116b) may not be formed in the region adjacent to the second surface (S2) within the substrate 112. For example, the outer pixel isolation structure (116a) may extend closer to the second surface (S2) of the substrate 112 than the inner pixel isolation structure (116b). At this time, the outer pixel isolation structure (116a) may extend only to a region adjacent to the second surface (S2) without penetrating the substrate 112, or may extend to penetrate the substrate 112.

The outer pixel isolation structure (116a) may be disposed to contact the first surface (S1) of the substrate 112, and may be spaced apart from or in contact with the second surface (S2) of the substrate 112. The central portion of the inner pixel isolation structures (116b) may be spaced apart from the first surface (S1) and the second surface (S2) of the substrate 112. The peripheral portion of the inner pixel isolation structures (116b) may be disposed to contact the first surface (S1) of the substrate 112 and may be spaced apart from the second surface (S2) of the substrate 112. Both the central portion and the peripheral portion of the inner pixel isolation structures (116b) may be spaced apart from the second surface (S2) by the same distance.

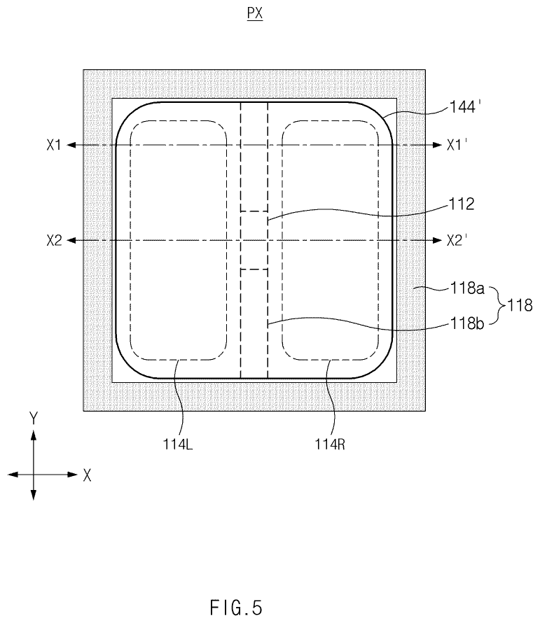

FIG. 5 is a plan view illustrating an example of a planar structure of the unit pixel (PX) according to another embodiment of the disclosed technology.

Referring to FIG. 5, the unit pixel (PX) may include a 2 PD (2 photodiode) structure including two photoelectric conversion elements (114L, 114R) disposed within a substrate, and the photoelectric conversion elements (114L, 114R) may share one microlens (144′).

The photoelectric conversion elements (114L, 114R) may be physically isolated from each other by a pixel isolation structure 118. For example, the pixel isolation structure 118 may include an outer pixel isolation structure (118a) disposed between adjacent unit pixels (PXs) to surround the unit pixel (PX); and an inner pixel isolation structure (118b) disposed between the photoelectric conversion elements (114L, 114R) within the unit pixel (PX). The outer pixel isolation structure (118a) and the inner pixel isolation structure (118b) may be formed to have the same width. The photoelectric conversion elements (114L, 114R) within one unit pixel (PX) may be disposed at both sides of the inner pixel isolation structure (118b).

The pixel isolation structure 118 may include a BDTI structure extending from the back surface (e.g., the surface upon which light is incident) of the semiconductor substrate into the interior of the substrate. The inner pixel isolation structure (118b) may extend in the first direction or the second direction so that both ends of the inner pixel isolation structure (118b) are connected to the outer pixel isolation structure (118a). Although FIG. 5 illustrates the inner pixel isolation structure (118b) extending in the second direction for convenience of description, it should be noted that the inner pixel isolation structure (118b) can also extend in the first direction.

A central portion of the inner pixel isolation structure (118b) may be spaced apart from the back surface of the substrate 112, and a peripheral portion located at both sides of the central portion of the inner pixel isolation structure (118b) may contact the back surface of the substrate 112.

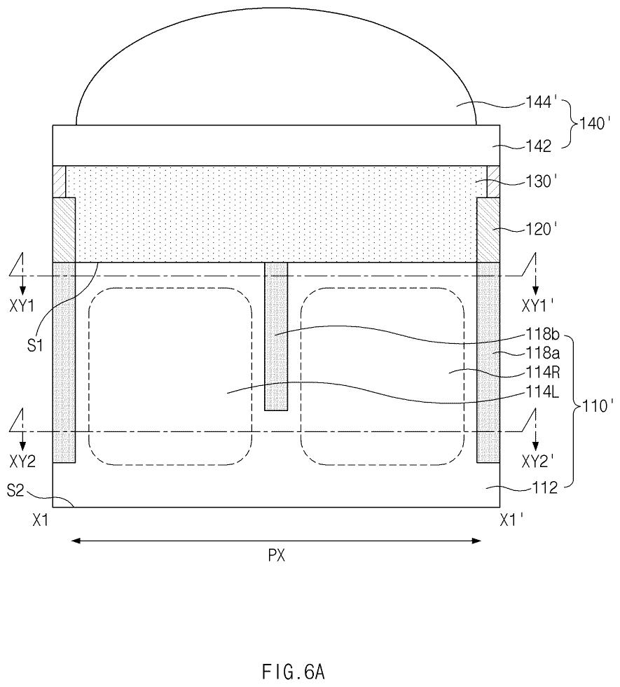

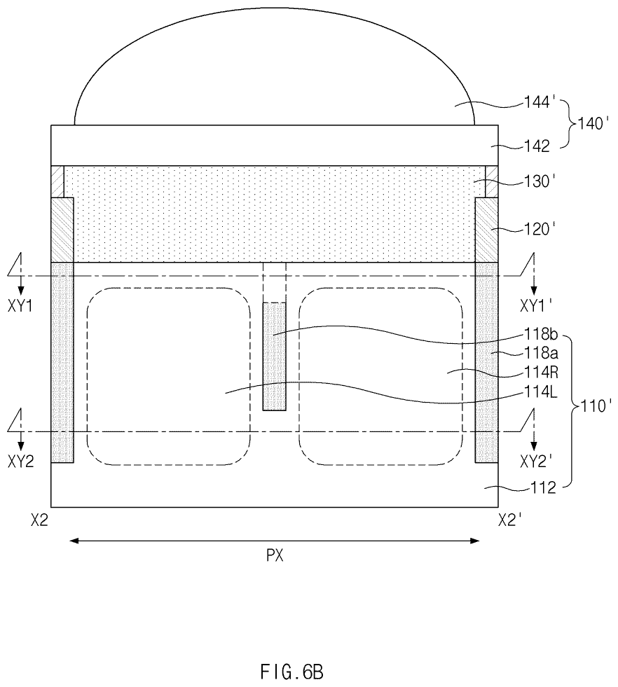

FIG. 6A is a cross-sectional view illustrating an example of the planar structure vertically taken along the line X1-X1′ of FIG. 5 according to another embodiment of the disclosed technology. FIG. 6B is a cross-sectional view illustrating an example of the planar structure vertically taken along the line X2-X2′ of FIG. 5 according to another embodiment of the disclosed technology.

Referring to FIGS. 6A and 6B, the pixel region 100 may include a substrate layer (110′), a grid structure (120′), a color filter layer (130′), and a lens layer (140′).

The substrate layer (110′) may include a substrate 112; and photoelectric conversion elements (114L, 114R) and pixel isolation structures (118a, 118b) formed within the substrate 112. The substrate 112 may include a first surface (e.g., a back surface) (S1) and a second surface (e.g., a front surface) (S2) facing or opposite to the first surface (S1).

The photoelectric conversion elements (114L, 114R) may be formed at both sides of the inner pixel isolation structure (118b) within one unit pixel (PX). The photoelectric conversion elements (114L, 114R) may generate photocharges through photoelectric conversion of incident light received through the lens layer (140′) and the color filter layer (130′). The photoelectric conversion elements (114L, 114R) may include N-type impurities.

The outer pixel isolation structure (118a) may be located outside the photoelectric conversion elements (114L, 114R) so as to surround the photoelectric conversion elements (114L, 114R), and the inner pixel isolation structure (118b) may be disposed between the photoelectric conversion elements (114L, 114R) within the unit pixel (PX). Each of the pixel isolation structures (118a, 118b) may include a BDTI structure extending from the first surface (S1) of the substrate 112 into the interior of the substrate. However, a central portion of the inner pixel isolation structure (118b) may not extend from the first surface (S1) of the substrate 112 but may be spaced apart from the first surface (S1) of the substrate 112 by a predetermined distance. The outer pixel isolation structure (118a) and the inner pixel isolation structure (118b) may extend to have different lengths.

The outer pixel isolation structure (118a) may vertically extend in the depth direction from the first surface (S1) of the substrate 112 but may extend to be spaced apart from the second surface (S2) by a first distance. Alternatively, the outer pixel isolation structure (118a) may extend from the first surface (S1) of the substrate 112 to the second surface (S2) so as to penetrate the substrate 112. A peripheral portion of the inner pixel isolation structure (118b) may extend vertically in the depth direction from the first surface (S1) of the substrate 112 but may extend to be spaced apart from the second surface (S2) by a second distance longer than the first distance. The central portion of the inner pixel isolation structure 118b may be spaced apart from both the first surface (S1) and the second surface (S2) of the substrate 112. In this case, the central portion of the inner pixel isolation structure 118b may also be spaced apart from the second surface (S2) by a second distance.

The central portion of the inner pixel isolation structure 118b may be formed to extend from the first surface (S1) of the substrate 112 in the same manner as in the peripheral portion, and may be etched and removed by a predetermined distance from the first surface (S1), so that the central portion of the inner pixel isolation structure 118b may be formed to be spaced apart from the first surface (S1). At this time, a bottom surface of the region formed when the central portion of the inner pixel isolation structure (118b) is etched may be located below a position at which incident light is focused by the microlens 144.

The substrate region formed above the central portion of the inner pixel isolation structure (118b) may be formed through an epitaxial growth process after the central portion of the inner pixel isolation structure (118b) is removed.

The grid structure (120′) may be formed between adjacent color filters over the first surface (S1) of the substrate 112 to prevent crosstalk between the color filters.

The grid structure (120′) may be disposed to overlap the outer pixel isolation structure (118a) in the vertical direction. However, the grid structure (120′) may not be disposed over the inner pixel isolation structure (118b). The grid structure (120′) may include a metal (e.g., tungsten).

The color filter layer (130′) may include color filters that filter out visible light from incident light received through the lens layer (140′). The color filters may be disposed in a region defined by the grid structure (120′). For example, the color filter may be formed to correspond to each unit pixel (PX).

The lens layer (140′) may include an overcoating layer 142 and a plurality of microlenses (144′). The overcoating layer 142 may be formed over the color filter layer (130′). The microlenses (144′) may be disposed over the overcoating layer 142, and may converge incident light onto the substrate layer 110. Each microlens (144′) may be formed to be shared by two photoelectric conversion elements (114L, 114R).

Even in the 2 PD structure as in the present embodiment, the incident light is designed to be focused on the central portion of the inner pixel isolation structure (118b) by the microlens 144. However, if the overlay of the microlens 144 is misaligned, a channel deviation may occur between the photoelectric conversion elements (114L, 114R). Therefore, even in the present embodiment, a region adjacent to the first surface (S1) of the substrate 112 from among the central portion of the inner pixel isolation structure (118b) is removed, and the removed region is filled with the same material as the substrate 112, so that the channel imbalance between the photoelectric conversion elements (114L, 114R) can be minimized.

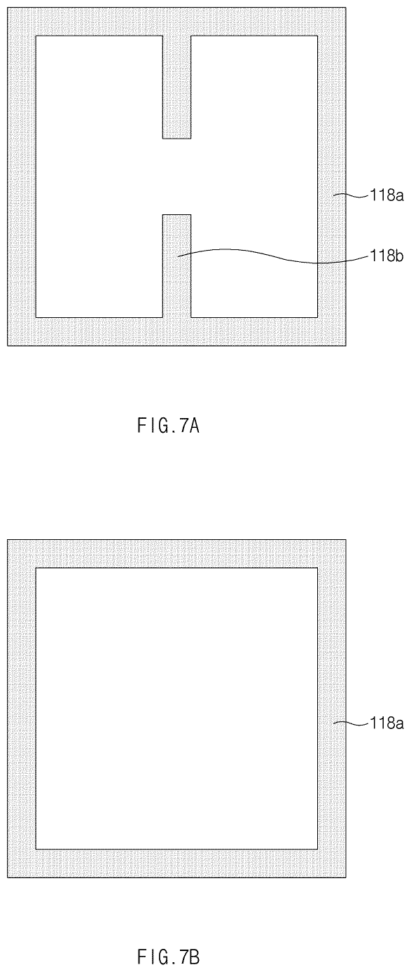

FIG. 7A is a cross-sectional view illustrating an example of the planar structure horizontally taken along the line XY1-XY1′ of FIG. 6A according to another embodiment of the disclosed technology. FIG. 7B is a cross-sectional view illustrating an example of the planar structure horizontally taken along the line XY2-XY2′ of FIG. 6B according to another embodiment of the disclosed technology.

Referring to FIG. 7A, in a region adjacent to the first surface (S1) of the substrate 112, the outer pixel isolation structure (118a) and the peripheral portion of the inner pixel isolation structure (118b) may be formed, but the central portion of the inner pixel isolation structure (118b) may not be formed. Referring to FIG. 7B, in a region adjacent to the second surface (S2) of the substrate 112, only the outer pixel isolation structure (118a) may be formed, but the inner pixel isolation structure (118b) may not be formed.

For example, the outer pixel isolation structure (118a) may contact the first surface (S1) of the substrate 112, and may be spaced apart from the second surface (S2) of the substrate 112 by a first distance. The peripheral portion of the inner pixel isolation structure (118b) may contact the first surface (S1) of the substrate 112, and may be spaced apart from the second surface (S2) of the substrate 112 by a second distance longer than the first distance. The central portion of the inner pixel isolation structure (118b) may be spaced apart from the second surface (S2) by the second distance while being spaced apart from the first surface (S1).

As is apparent from the above description, the image sensing device based on some embodiments of the disclosed technology may alleviate overlay sensitivity caused by misalignment or poor isolation between layers or components by improving the pixel isolation structure.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device, comprising:
a substrate including a first surface upon which light is incident and a second surface facing or opposite to the first surface;
a microlens disposed over the first surface of the substrate;
a plurality of photoelectric conversion elements supported by the substrate and arranged adjacent to each other, each photoelectric conversion element configured to receive incident light through the microlens and generate photocharges corresponding to the incident light; and
a first pixel isolation structure disposed between the plurality of photoelectric conversion elements within the substrate and configured to isolate the plurality of photoelectric conversion elements from each other,
wherein the first pixel isolation structure includes a first portion spaced apart from the first surface and a second portion being in contact with the first surface.

2. The image sensing device according to claim 1, wherein:
the first portion and the second portion are spaced apart from the second surface.

3. The image sensing device according to claim 2, wherein:
a separation distance between the first portion and the second surface is equal to a separation distance between the second portion and the second surface.

4. The image sensing device according to claim 2, further comprising:
a floating diffusion region disposed in a region overlapping the first portion on the second surface.

5. The image sensing device according to claim 1, wherein the first pixel isolation structure includes:
a first isolation portion configured to extend in a first direction between the plurality of photoelectric conversion elements; and
a second isolation portion configured to extend in a second direction intersecting the first direction between the plurality of photoelectric conversion elements.

6. The image sensing device according to claim 5, wherein:
the plurality of photoelectric conversion elements is arranged adjacent to each other in a (2×2) matrix structure including two rows and two columns.

7. The image sensing device according to claim 1, wherein:
the first pixel isolation structure extends in a first direction or a second direction intersecting the first direction between the plurality of photoelectric conversion elements.

8. The image sensing device according to claim 7, wherein:
the plurality of photoelectric conversion elements is disposed at two sides of the first pixel isolation structure within one unit pixel.

9. The image sensing device according to claim 1, further comprising:
a second pixel isolation structure connected to the first pixel isolation structure, and configured to surround the plurality of photoelectric conversion elements.

10. The image sensing device according to claim 9, wherein:
the second pixel isolation structure extends from the first surface toward the second surface, and is spaced apart from the second surface by a first distance.

11. The image sensing device according to claim 10, wherein:
the first pixel isolation structure is spaced apart from the second surface by a second distance longer than the first distance.

12. The image sensing device according to claim 9, wherein:
the second pixel isolation structure extends from the first surface to the second surface to penetrate the substrate.

13. An image sensing device, comprising:
a substrate including a first surface upon which light is incident and a second surface facing or opposite to the first surface;
a plurality of photoelectric conversion elements supported by the substrate and arranged adjacent to each other, each photoelectric conversion element configured to share one microlens and generate photocharges corresponding to the incident light; and
a first pixel isolation structure disposed between the plurality of photoelectric conversion elements within the substrate and configured to isolate the plurality of photoelectric conversion elements from each other,
wherein the first pixel isolation structure includes a first portion disposed within the substrate and spaced apart from the first surface and the second surface.

14. The image sensing device according to claim 13, wherein:
the first pixel isolation structure further includes a second portion in contact with the first surface and spaced apart from the second surface.

15. The image sensing device according to claim 14, wherein:
a separation distance between the first portion and the second surface is equal to a separation distance between the second portion and the second surface.

16. The image sensing device according to claim 13, wherein:
the plurality of photoelectric conversion elements is arranged adjacent to each other in a (2×2) matrix structure including two rows and two columns.

17. The image sensing device according to claim 13, further comprising:
a floating diffusion region disposed in a region overlapping the first portion on the second surface.

18. The image sensing device according to claim 13, wherein:
the plurality of photoelectric conversion elements is disposed at two sides of the first pixel isolation structure within one unit pixel.

19. The image sensing device according to claim 13, further comprising:
a second pixel isolation structure connected to the first pixel isolation structure, and configured to surround the plurality of photoelectric conversion elements.

20. The image sensing device according to claim 19, wherein:
a separation distance between the second pixel isolation structure and the second surface is shorter than a separation distance between the first pixel isolation structure and the second surface.
